(19) United States
(12) Patent Application Publication
(10) Pub. No.: US 2025/0022952 A1
(43) Pub. Date: Jan. 16, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hyuga SAITO, Nonoichi Ishikawa (JP); Hirofumi KAWAI, Nonoichi Ishikawa (JP); Saya SHIMOMURA, Kanazawa Ishikawa (JP); Hiroyuki KISHIMOTO, Kanazawa Ishikawa (JP); Takuya YASUTAKE, Kanazawa Ishikawa (JP); Hiroaki KATOU, Nonoichi Ishikawa (JP); Katsura MIYASHITA, Naka Kanagawa (JP); Hiroki NEMOTO, Fuchu Tokyo (JP)

(21) Appl. No.: 18/626,854

(22) Filed: Apr. 4, 2024

(30) Foreign Application Priority Data
Jul. 13, 2023 (JP) 2023-115146

(51) Int. Cl. H01L 29/78; H01L 29/40; H01L 29/423

(52) U.S. Cl. CPC H01L 29/7813; H01L 29/407; H01L 29/4236

(57) ABSTRACT

The trench structure part includes a field plate electrode, a first insulating film, a second insulating film, the second insulating film extending to be more proximate to the first surface than the first insulating film, a gate electrode including a first portion located on the second insulating film, and a second portion located on the first insulating film, the second portion being thicker than the first portion, and a third insulating film. The gate contact part extends from the gate wiring layer toward the second portion and contacts the second portion. The gate contact part is not positioned between the first portion and the gate wiring layer. The first portion is positioned adjacent, in a second direction orthogonal to the first direction, to a lower end portion of the gate contact part contacting the second portion.

### CROSS-REFERENCE TO RELATED APPLICATION

This application is based upon and claims the benefit of priority from Japanese Patent Application No. 2023-115146, filed on Jul. 13, 2023; the entire contents of which are incorporated herein by reference.

### FIELD

Embodiments described herein relate generally to a semiconductor device.

### BACKGROUND

A known structure of a semiconductor device has a trench gate structure in which a field plate electrode is located under a gate electrode. One such structure includes an upwardly convex insulating film located between the gate electrode and the field plate electrode.

### BRIEF DESCRIPTION OF THE DRAWINGS

FIG. 1 is a schematic plan view of a semiconductor device of an embodiment;

FIG. 2 is an A-A cross-sectional view of FIG. 1;

FIG. 3 is a B-B cross-sectional view of FIG. 1;

FIG. 4 is a C-C cross-sectional view of FIG. 1;

FIG. 5 is a D-D cross-sectional view of FIG. 1; and

FIGS. 6A to 6C are schematic plan views showing arrangement examples of gate contact parts.

### DETAILED DESCRIPTION

According to one embodiment, a semiconductor device includes a semiconductor layer including a first surface, and a second surface positioned at a side opposite to the first surface in a first direction; a trench structure part extending from the first surface in the first direction; a gate wiring layer located on the first surface and on the trench structure part; and a gate contact part extending from the gate wiring layer toward the trench structure part. The trench structure part includes a field plate electrode, a first insulating film located between the field plate electrode and the semiconductor layer, a second insulating film located on the field plate electrode, the second insulating film extending to be more proximate to the first surface than the first insulating film, a gate electrode including a first portion located on the second insulating film, and a second portion located on the first insulating film, the second portion being thicker than the first portion, and a third insulating film located between the semiconductor layer and the second portion of the gate electrode. The gate contact part extends from the gate wiring layer toward the second portion and contacts the second portion. The gate contact part is not positioned between the first portion and the gate wiring layer. The first portion is positioned adjacent, in a second direction orthogonal to the first direction, to a lower end portion of the gate contact part contacting the second portion.

Embodiments will now be described with reference to the drawings. The same configurations are marked with the same reference numerals in the drawings. Although the first conductivity type is an n-type and the second conductivity type is a p-type in the description of the embodiments described below, the first conductivity type may be the p-type, and the second conductivity type may be the n-type.

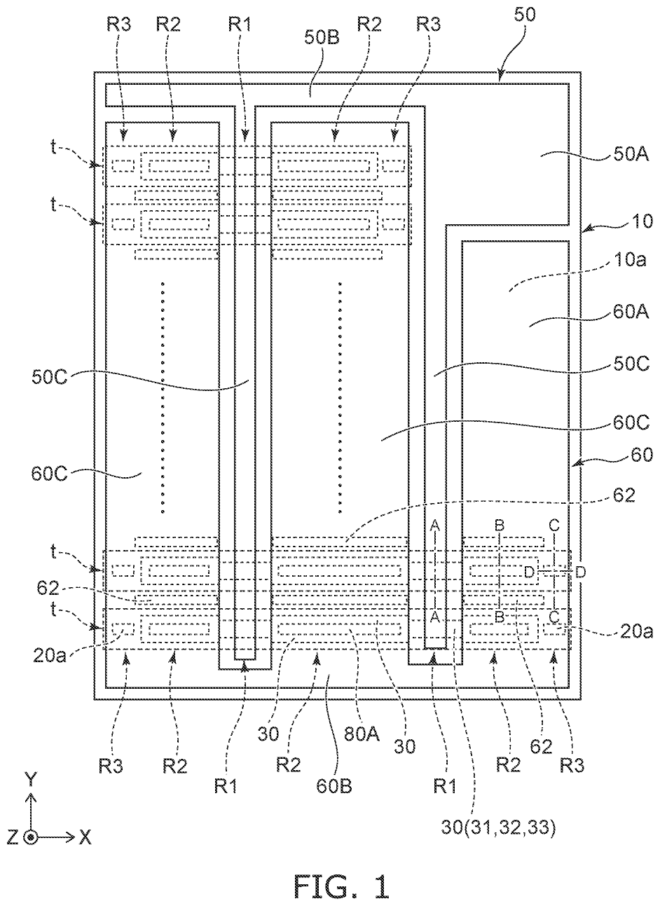

A semiconductor device of an embodiment will now be described with reference to FIGS. 1 to 5. The semiconductor device of the embodiment includes a semiconductor layer 10, a trench structure part t, a gate wiring layer 50, and a gate contact part 55.

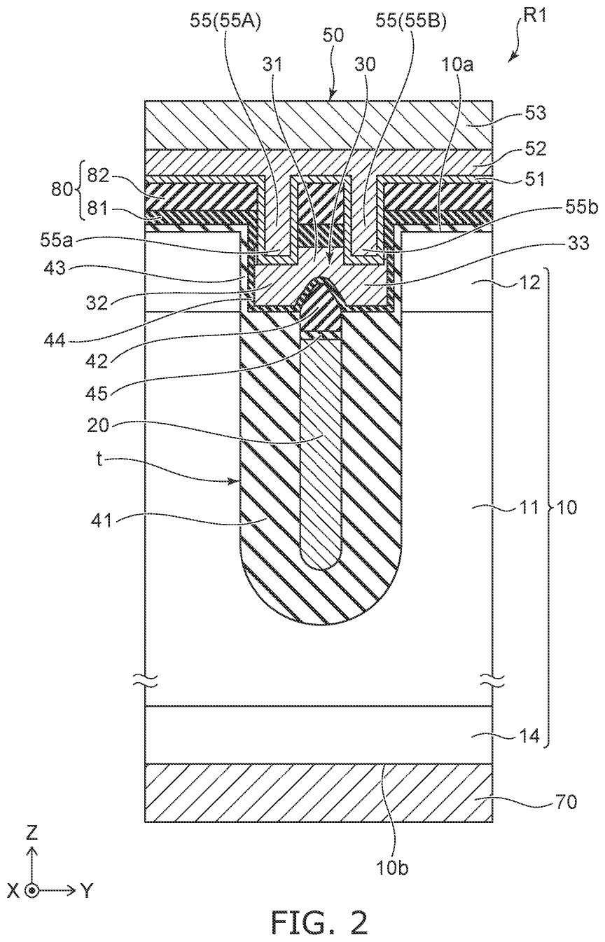

As shown in FIGS. 2 to 5, the semiconductor layer 10 includes a first surface 10a and a second surface 10b. A direction connecting the first surface 10a and the second surface 10b with a shortest distance is taken as a first direction Z. The second surface 10b is positioned at the side opposite to the first surface 10a in the first direction Z. Two directions orthogonal to the first direction Z are taken as a second direction Y and a third direction X. The second direction Y and the third direction X are orthogonal to each other.

In the specification, “thickness” refers to the maximum value of the thickness in a specific direction (the first direction Z, the second direction Y, or the third direction X).

For example, silicon can be used as the material of the semiconductor layer 10. Or, for example, silicon carbide, gallium nitride, etc., may be used as the material of the semiconductor layer 10.

As shown in FIG. 2, the trench structure part t extends along the first direction Z from the first surface 10a and is positioned inside the semiconductor layer 10 when viewed in cross-section. As shown in FIG. 1, the trench structure part t extends in the third direction X when viewed in plan. For example, multiple trench structure parts t extend in the third direction X. The multiple trench structure parts t are arranged in the second direction Y.

The trench structure part t includes a field plate electrode 20, a first insulating film 41, a second insulating film 42, a third insulating film 43, and a gate electrode 30. These components are located inside a trench formed in the semiconductor layer 10. The field plate electrode 20, the first insulating film 41, the second insulating film 42, and the third insulating film 43 extend in the third direction X inside the trench.

The field plate electrode 20 relaxes electric field concentration at the vicinity of the gate electrode 30 inside the semiconductor layer 10. For example, polycrystalline silicon can be used as the material of the field plate electrode 20.

The first insulating film 41 is located between the field plate electrode 20 and the semiconductor layer 10. The first insulating film 41 is located between the semiconductor layer 10 and the side surface of the field plate electrode 20 and between the semiconductor layer 10 and the lower end of the field plate electrode 20. For example, a silicon oxide film can be used as the first insulating film 41.

The second insulating film 42 is located on the field plate electrode 20 and extends to be more proximate to the first surface 10a of the semiconductor layer 10 than the first insulating film 41. The upper end of the second insulating film 42 is positioned to be more proximate to the first surface 10a than the upper end of the first insulating film 41. For example, a BPSG (boro-phospho silicate glass) film can be used as the second insulating film 42.

The gate electrode 30 includes a first portion 31 located on the second insulating film 42, and a second portion 32 located on the first insulating film 41. The second insulating film 42 is positioned between the field plate electrode 20 and the first portion 31 in the first direction Z. The first portion 31 and the second portion 32 are a continuous body of the same material. For example, polycrystalline silicon can be used as the material of the gate electrode 30.

The thickness in the first direction Z of the second portion 32 is greater than the thickness in the first direction Z of the first portion 31. Conversely speaking, the thickness in the first direction Z of the first portion 31 is less than the thickness in the first direction Z of the second portion 32. Because the second insulating film 42 extends into the gate electrode 30, the first portion 31 of the gate electrode 30 positioned on the second insulating film 42 is thinner than the second portion 32 of the gate electrode 30 at which the second insulating film 42 does not extend.

The second insulating film 42 extends into the gate electrode 30 so that a portion of the gate electrode 30 is more concave toward the upper surface of the gate electrode 30 than the lower surface of the second portion 32. As a result, compared to when the second insulating film 42 does not extend into the gate electrode 30, the distance in the first direction Z between the field plate electrode 20 and the gate electrode 30 can be lengthened. The dielectric breakdown immunity between the gate electrode 30 and the field plate electrode 20 can be increased thereby. Also, the capacitance between the gate electrode 30 and the field plate electrode 20 can be reduced, and the switching speed can be increased. It is favorable for the second insulating film 42 to extend into the gate electrode 30 from the lower surface of the second portion 32 not less than 25% of the thickness in the first direction Z of the second portion 32.

The third insulating film 43 is located between the semiconductor layer 10 and the side surface of the second portion 32 of the gate electrode 30. For example, a silicon oxide film can be used as the third insulating film 43.

The gate wiring layer 50 is located on the first surface 10a of the semiconductor layer 10 and on the trench structure part t with an inter-layer insulating layer 80 interposed. The gate wiring layer 50 can include, for example, a first metal film 51 located on the inter-layer insulating layer 80, a second metal film 52 located on the first metal film 51, and a third metal film 53 located on the second metal film 52. For example, a titanium film can be used as the first metal film 51; a tungsten film can be used as the second metal film 52; and an aluminum film can be used as the third metal film 53. The thicknesses in the first direction Z of the second and third metal films 52 and 53 each are greater than the thickness in the first direction Z of the first metal film 51. The first metal film 51 functions as a barrier film preventing diffusion of the metals of the second and third metal films 52 and 53.

As shown in FIG. 1, the gate wiring layer 50 can include a gate pad 50A, a first extension part 50B, and a second extension part 50C. For example, a first connection member such as a wire or the like is bonded to the gate pad 50A. The gate wiring layer 50 is electrically connected with a gate drive circuit via the first connection member. The first extension part 50B extends in the third direction X from the gate pad 50A. The second extension part 50C extends in the second direction Y from the gate pad 50A or the first extension part 50B. Multiple second extension parts 50C extend in the second direction Y.

As shown in FIG. 2, the inter-layer insulating layer 80 can include, for example, a first layer 81 located on the first surface 10a of the semiconductor layer 10 and on the trench structure part t, and a second layer 82 located on the first layer 81. For example, silicon oxide can be used as the material of the first layer 81; and BPSG can be used as the material of the second layer 82.

The gate contact part 55 extends from the gate wiring layer 50 toward the trench structure part t. For example, the gate contact part 55 extends from the second metal film 52 toward the trench structure part t. For example, the gate contact part 55 can include a portion including the same material as the second metal film 52, and the first metal film 51 that covers the surface of the portion.

The gate contact part 55 extends from the gate wiring layer 50 toward the second portion 32 of the gate electrode 30 and contacts the second portion 32. The gate contact part 55 that contacts the second portion 32 may be referred to as a first gate contact part 55A to differentiate from the gate contact part 55 (a second gate contact part 55B) contacting a third portion 33 described below. The gate electrode 30 is electrically connected with the gate wiring layer 50 via the gate contact part 55. In the example shown in FIG. 1, the gate contact part 55 is positioned at the portion at which the gate electrode 30 and the second extension part 50C of the gate wiring layer 50 cross.

The gate contact part 55 is formed by forming a contact trench that extends through the inter-layer insulating layer 80 to reach the gate electrode 30, and then filling the contact trench with a metal material. For example, the contact trench can be formed by RIE (Reactive Ion Etching). According to the embodiment, the gate contact part 55 is not positioned between the gate wiring layer 50 and the first portion 31 of the gate electrode 30. Therefore, the contact trench can be prevented from extending through the thin first portion 31 of the gate electrode 30 and undesirably reaching the field plate electrode 20 below the first portion 31. As a result, short-circuits between the gate electrode 30 and the field plate electrode 20 via the gate contact part 55 can be prevented, and the reliability of the semiconductor device can be increased. The thickness in the first direction Z of the first portion 31 is, for example, not more than 500 nm.

In the second direction Y, the first portion 31 is positioned adjacent to a lower end portion 55a of the first gate contact part 55A contacting the second portion 32. As a result, a reduction of the cross-sectional area of the gate electrode 30 at the upper surface side of the gate electrode 30 connected to the gate contact part 55 can be suppressed, and a rise of the gate resistance can be suppressed while thinning a portion of the gate electrode 30 and increasing the distance between the gate electrode 30 and the field plate electrode 20.

The gate electrode 30 further includes the third portion 33 that is positioned adjacent to the first portion 31 in the second direction Y and located on the first insulating film 41. The thickness in the first direction Z of the third portion 33 is greater than the thickness in the first direction Z of the first portion 31. The first portion 31 is positioned between the second portion 32 and the third portion 33 in the second direction Y. The first portion 31, the second portion 32, and the third portion 33 are a continuous body of the same material.

At least two gate contact parts 55A and 55B that are positioned distant to each other in the second direction Y are provided for one trench structure part t. As described above, the first gate contact part 55A among the two gate contact parts 55A and 55B extends from the gate wiring layer 50 toward the second portion 32 of the gate electrode 30 and contacts the second portion 32. The second gate contact part 55B among the two gate contact parts 55A and 55B extends from the gate wiring layer 50 toward the third portion 33 and contacts the third portion 33. Because the two gate contact parts 55A and 55B contact the gate electrode 30 of one trench structure part t, the contact area between the gate wiring layer 50 and the gate electrode 30 can be increased, and the gate resistance can be reduced.

In the second direction Y, the first portion 31 is positioned between the lower end portion 55a of the first gate contact part 55A contacting the second portion 32 and a lower end portion 55b of the second gate contact part 55B contacting the third portion 33. As a result, a reduction of the cross-sectional area of the gate electrode 30 at the upper surface side of the gate electrode 30 connected to the gate contact part 55 can be suppressed, and a rise of the gate resistance can be suppressed.

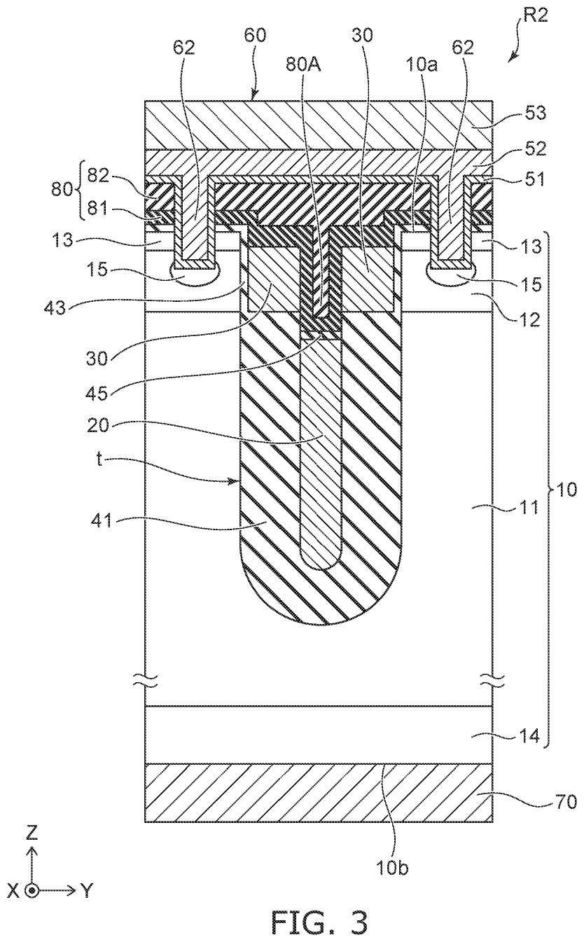

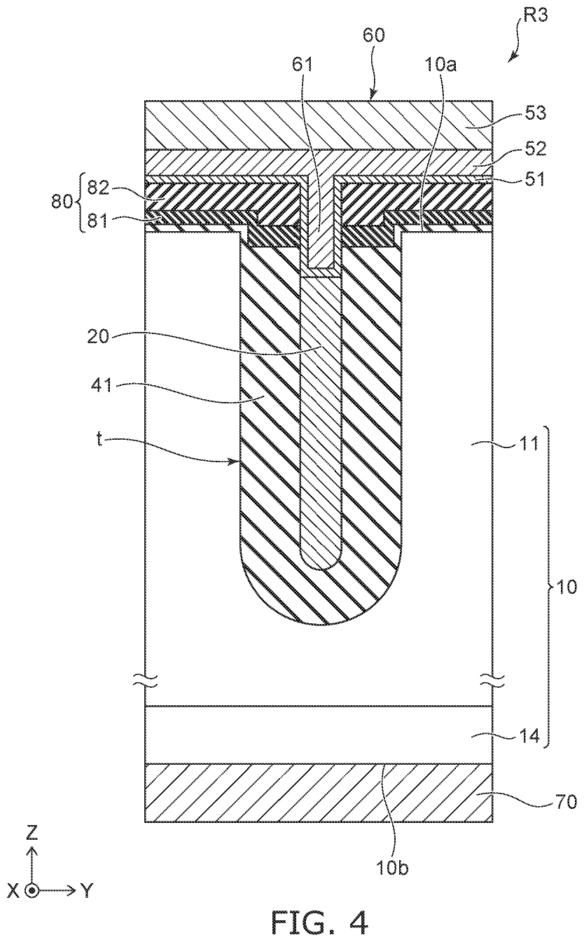

As shown in FIGS. 3 and 4, the semiconductor device of the embodiment further includes a first electrode layer 60 located on the first surface 10a of the semiconductor layer 10 and on the trench structure part t. The first electrode layer 60 is located on the first surface 10a and on the trench structure part t with the inter-layer insulating layer 80 interposed.

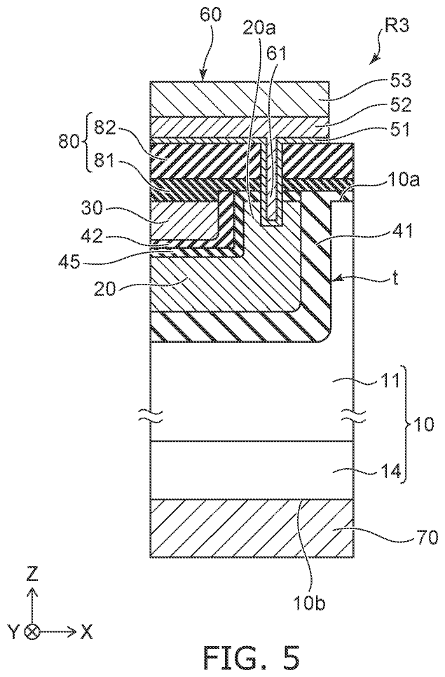

As described below with reference to FIGS. 4 and 5, the field plate electrode 20 is electrically connected with the first electrode layer 60. Accordingly, the same potential is applied to the first electrode layer 60 and the field plate electrode 20.

For example, the first electrode layer 60 and the gate wiring layer 50 can be simultaneously formed of the same material. In such a case, similarly to the gate wiring layer 50 described above, the first electrode layer 60 can include the first metal film 51, the second metal film 52, and the third metal film 53.

As shown in FIG. 1, the first electrode layer 60 is separated from the gate wiring layer 50 on the first surface 10a of the semiconductor layer 10 and on the trench structure part t. The first electrode layer 60 can include a first pad 60A, a third extension part 60B, and fourth extension parts 60C. For example, a second connection member such as a wire or the like is bonded to the first pad 60A. The first electrode layer 60 is electrically connected with an external circuit via the second connection member. The third extension part 60B extends in the third direction X from the first pad 60A. The multiple fourth extension parts 60C extend in the second direction Y from the third extension part 60B. In the third direction X, the second extension part 50C of the gate wiring layer 50 is positioned between the fourth extension parts 60C of the first electrode layer 60 and between the fourth extension part 60C and the first pad 60A.

As shown in FIG. 1, the semiconductor device of the embodiment includes a first region R1, a second region R2, and a third region R3. The first region R1, the second region R2, and the third region R3 are arranged in the third direction X.

The first region R1 includes a crossing portion between the trench structure part t and the second extension part 50C of the gate wiring layer 50. In the first region R1 as shown in FIG. 2, the gate electrode 30 includes the first portion 31, the second portion 32, and the third portion 33. In the first region R1, the second insulating film 42 is located between the field plate electrode 20 and the first portion 31 of the gate electrode 30. In the first region R1, the gate contact part 55 contacts the second and third portions 32 and 33 of the gate electrode 30.

As shown in FIGS. 2 to 4, the semiconductor layer 10 includes an n-type first semiconductor part 11, and a p-type second semiconductor part 12 located on the first semiconductor part 11. The semiconductor layer 10 also includes an n-type fourth semiconductor part 14. The first semiconductor part 11 is located on the fourth semiconductor part 14. The n-type impurity concentration of the fourth semiconductor part 14 is greater than the n-type impurity concentration of the first semiconductor part 11. The surface of the fourth semiconductor part 14 at the side opposite to the first semiconductor part 11 is used as the second surface 10b of the semiconductor layer 10. In the first region R1, the upper surface of the second semiconductor part 12 is used as the first surface 10a of the semiconductor layer 10. The semiconductor device of the embodiment includes a second electrode layer 70 that is located at the second surface 10b and is electrically connected with the fourth semiconductor part 14. The first semiconductor part 11, the fourth semiconductor part 14, and the second electrode layer 70 are located in the first region R1, the second region R2, and the third region R3.

In the second region R2 as shown in FIG. 3, the semiconductor layer 10 further includes an n-type third semiconductor part 13 located on the second semiconductor part 12. The n-type impurity concentration of the third semiconductor part 13 is greater than the n-type impurity concentration of the first semiconductor part 11. In the second region R2, the upper surface of the third semiconductor part 13 is used as the first surface 10a of the semiconductor layer 10.

In the second region R2, the first electrode layer 60 is located on the first surface 10a of the semiconductor layer 10 and on the trench structure part t with the inter-layer insulating layer 80 interposed. The third semiconductor part 13 is electrically connected with the first electrode layer 60.

In the second region R2, a second contact part 62 extends from the first electrode layer 60 toward the second semiconductor part 12. The second contact part 62 extends through the inter-layer insulating layer 80 and the third semiconductor part 13 and contacts a p-type fifth semiconductor part 15 located inside the second semiconductor part 12. The p-type impurity concentration of the fifth semiconductor part 15 is greater than the p-type impurity concentration of the second semiconductor part 12. In the second region R2, the second semiconductor part 12 and the third semiconductor part 13 are electrically connected with the first electrode layer 60 via the second contact part 62. In the example shown in FIG. 3, the side surface of the second contact part 62 contacts the third semiconductor part 13. In the second region R2, multiple second contact parts 62 are arranged in the second direction Y. The second contact part 62 is positioned between the adjacent trench structure parts t in the second direction Y.

In the second region R2, the gate electrode 30 of one trench structure part t is divided in the second direction Y. In the second region R2, a portion 80A of the inter-layer insulating layer 80 extends toward the field plate electrode 20 and divides the gate electrode 30 in the second direction Y. The side surfaces of the gate electrodes 30 divided in the second direction Y face the second semiconductor part 12 via the third insulating film 43.

For example, the semiconductor device of the embodiment has a MOSFET (Metal-Oxide-Semiconductor Field Effect Transistor) structure. For example, the first electrode layer 60 functions as a source electrode; the second electrode layer 70 functions as a drain electrode; the first semiconductor part 11 functions as a drift layer; the second semiconductor part 12 functions as a base layer; the third semiconductor part 13 functions as a source layer; and the fourth semiconductor part 14 functions as a drain layer.

An n-type inversion layer (a channel) is formed in the portion of the second semiconductor part 12 facing the gate electrode 30 in the second region R2 when a first potential (e.g., a ground potential) is applied to the first electrode layer 60, a second potential (e.g., a positive potential) that is greater than the first potential is applied to the second electrode layer 70, and a gate voltage that is not less than a threshold is applied to the gate electrode 30. Then, in the second region R2, a current flows between the second electrode layer 70 (the drain electrode) and the first electrode layer 60 (the source electrode) via the fourth semiconductor part 14 (the drain layer), the channel, and the third semiconductor part 13 (the source layer).

The semiconductor device of the embodiment may have an IGBT (Insulated Gate Bipolar Transistor) structure.

In the first region R1 as shown in FIG. 2, in addition to the third insulating film 43, a fourth insulating film 44 also is located between the second semiconductor part 12 and the second portion 32 of the gate electrode 30 and between the second semiconductor part 12 and the third portion 33 of the gate electrode 30. For example, a silicon oxide film can be used as the fourth insulating film 44. The thickness of the insulating film (the third insulating film 43 and the fourth insulating film 44) between the semiconductor layer 10 and the side surface of the gate electrode 30 in the first region R1 is greater than the thickness of the insulating film (the third insulating film 43) between the semiconductor layer 10 and the side surface of the gate electrode 30 in the second region R2 shown in FIG. 3. As a result, in the first region R1, the dielectric breakdown immunity between the gate electrode 30 and the first semiconductor part 11 to which the drain potential is applied can be increased. In particular, it is effective to increase dielectric breakdown immunity by increasing the thickness of the insulating film between the semiconductor layer 10 and the side surface of the gate electrode 30 because an electric field is directly applied from the first semiconductor part 11 to the portion of the gate electrode 30 that is not adjacent to the second semiconductor part 12 in the second direction Y.

As shown in FIG. 1, the third region R3 includes the two end portions of the trench structure part t in the third direction X. In the third region R3 as shown in FIG. 4, the first electrode layer 60 is located on the first surface 10a of the semiconductor layer 10 and on the trench structure part t with the inter-layer insulating layer 80 interposed. The third region R3 does not include the second semiconductor part 12 and the third semiconductor part 13. In the third region R3, the upper surface of the first semiconductor part 11 is used as the first surface 10a of the semiconductor layer 10.

In the third region R3, the gate electrode is not located on the field plate electrode 20; and a first contact part 61 is located on the field plate electrode 20. The first contact part 61 extends through the inter-layer insulating layer 80 from the first electrode layer 60, extends toward the field plate electrode 20, and contacts the field plate electrode 20. The field plate electrode 20 is electrically connected with the first electrode layer 60 via the first contact part 61.

As shown in FIG. 5, the field plate electrode 20 includes an extension part 20a that extends toward the first surface 10a side at the end portion of the trench structure part t in the third direction X. The first contact part 61 of the first electrode layer 60 is connected to the extension part 20a.

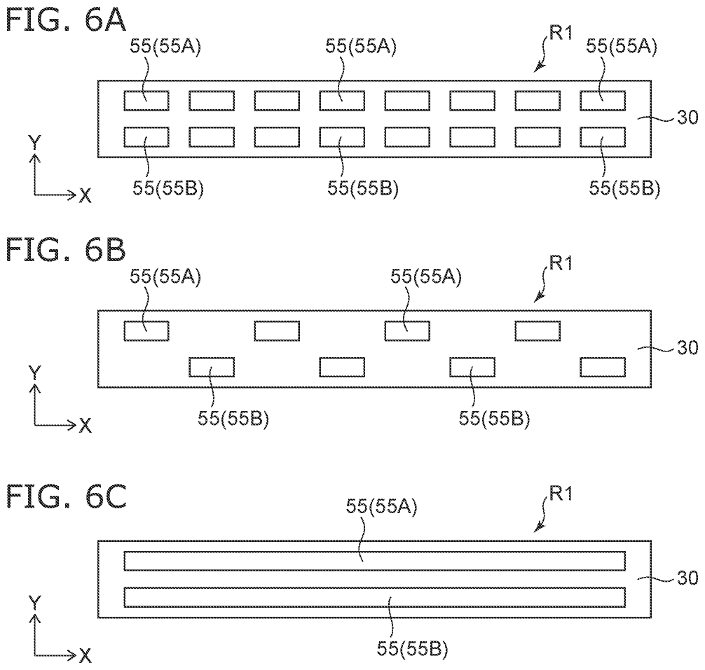

FIGS. 6A to 6C are schematic plan views showing an arrangement example of the multiple gate contact parts 55 in the first region R1.

In the example shown in FIGS. 6A and 6B, the multiple first gate contact parts 55A that are connected to the second portion 32 of the gate electrode 30 are arranged to be separated from each other in the third direction X; and the multiple second gate contact parts 55B that are connected to the third portion 33 of the gate electrode 30 are arranged to be separated from each other in the third direction X.

In the example shown in FIG. 6A, the first gate contact part 55A and the second gate contact part 55B are aligned with each other in the second direction Y.

In the example shown in FIG. 6B, the first gate contact part 55A and the second gate contact part 55B have a staggered arrangement and are not aligned with each other in the second direction Y.

In the example shown in FIG. 6C, the first gate contact part 55A continuously extends in the third direction X; and the second gate contact part 55B continuously extends in the third direction X.

As shown in FIG. 2, the trench structure part t in the first region R1 may include a fifth insulating film 45 located between the field plate electrode 20 and the second insulating film 42. The fifth insulating film 45 is, for example, a silicon oxide film formed by thermal oxidation treatment. In the second region R2 as shown in FIG. 3, the fifth insulating film 45 also may be located between the field plate electrode 20 and the portion 80A of the inter-layer insulating layer 80.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a semiconductor layer including
a first surface, and
a second surface positioned at a side opposite to the first surface in a first direction;
a trench structure part extending from the first surface in the first direction;
a gate wiring layer located on the first surface and on the trench structure part; and
a gate contact part extending from the gate wiring layer toward the trench structure part,
the trench structure part including
a field plate electrode,
a first insulating film located between the field plate electrode and the semiconductor layer,
a second insulating film located on the field plate electrode, the second insulating film extending to be more proximate to the first surface than the first insulating film,
a gate electrode including
a first portion located on the second insulating film, and
a second portion located on the first insulating film, the second portion being thicker than the first portion, and
a third insulating film located between the semiconductor layer and the second portion of the gate electrode,
the gate contact part extending from the gate wiring layer toward the second portion and contacting the second portion, the gate contact part not being positioned between the first portion and the gate wiring layer,
the first portion being positioned adjacent, in a second direction orthogonal to the first direction, to a lower end portion of the gate contact part contacting the second portion.

2. The device according to claim 1, wherein
the gate electrode further includes a third portion positioned adjacent to the first portion in the second direction,
the gate contact part extends from the gate wiring layer toward the third portion and contacts the third portion, and
the first portion is positioned, in the second direction, between the lower end portion of the gate contact part contacting the second portion and a lower end portion of the gate contact part contacting the third portion.

3. The device according to claim 1, wherein
the second insulating film extends into the gate electrode to not less than 25% of a thickness in the first direction of the second portion.

4. The device according to claim 1, further comprising:
a first electrode layer located on the first surface and on the trench structure part,
the first electrode layer being separated from the gate wiring layer,
the field plate electrode being electrically connected with the first electrode layer.

5. The device according to claim 4, wherein
the semiconductor layer includes:
a first semiconductor part of a first conductivity type;
a second semiconductor part located on the first semiconductor part, the second semiconductor part facing the gate electrode via the third insulating film, the second semiconductor part being of a second conductivity type; and
a third semiconductor part located on the second semiconductor part, the third semiconductor part being electrically connected with the first electrode layer, the third semiconductor part being of the first conductivity type.

6. The device according to claim 5, further comprising:
a first region in which the first and second portions of the gate electrode are located; and
a second region in which the third semiconductor part is located,
the gate electrode being divided in the second direction in the second region.

7. The device according to claim 6, further comprising:
a third region; and
a first contact part,
the gate electrode not being positioned on the field plate electrode in the third region,
the first contact part extending from the first electrode layer toward the field plate electrode and contacting the field plate electrode.

8. The device according to claim 5, further comprising:
a second contact part extending in the first direction from the first electrode layer and extending through the third semiconductor part,
a side surface of the second contact part contacting the third semiconductor part.

9. The device according to claim 7, wherein
the trench structure part further includes a fourth insulating film,
the fourth insulating film is provided with the third insulating film between the second semiconductor part and the second portion of the gate electrode in the first region, and
a thickness of the third and fourth insulating films between the semiconductor layer and a side surface of the gate electrode in the first region is greater than a thickness of the third insulating film between the semiconductor layer and a side surface of the gate electrode in the second region.

10. The device according to claim 1, wherein
the second insulating film is a BPSG (boro-phospho silicate glass) film.

11. The device according to claim 1, wherein
a plurality of the trench structure parts is arranged in the second direction.

12. The device according to claim 1, wherein
two of the gate contact parts extend from the gate wiring layer toward one of the trench structure parts.
